(19) United States
(12) Patent Application Publication
(10) Pub. No.: US 2010/0079942 A1
(43) Pub. Date: Apr. 1, 2010

(54) VIDEO DISPLAY APPARATUS

(76) Inventors: Taku Yamamoto, Yokohama (JP); Katsunari Sato, Toda (JP); Yoshiharu Yamashita, Yokohama (JP); Takeshi Miitsu, Isehara (JP); Hiroyoshi Ogura, Isehara (JP); Hiroki Hosono, Isehara (JP); Koichi Sato, Isehara (JP)

Correspondence Address: MCDERMOTT WILL & EMERY LLP, 600 13TH STREET, N.W., WASHINGTON, DC, 20005-3096, US

(21) Appl. No.: 12/426,616

(22) Filed: Apr. 20, 2009

(30) Foreign Application Priority Data
Sep. 26, 2008 (JP) 2008-247089

(51) Int. Cl. H05K 7/20; H02B 1/01

(52) U.S. Cl. 361/690; 361/829; 361/704

(57) ABSTRACT

The present invention provides a simply usable shield cover capable of enhancing the mechanical strength of a set even if a display device is decreased in thickness. In a video display apparatus including a base chassis on a front surface of which a displaying member is arranged and on a back surface of which a unit for driving and controlling the display device is arranged, and a plurality of frames arranged on the back surface of the base chassis in parallel with each other, a shield cover is attached to the plurality of frames to extend over those to form a crosslink structure.

### INCORPORATION BY REFERENCE

The present application claims priority from Japanese application No. 2008-247089 filed on Sep. 26, 2008, the content of which is hereby incorporated by reference into this application.

### BACKGROUND OF THE INVENTION

1. Field of the invention

The present invention relates to a video display apparatus using a flat panel such as a liquid crystal panel as a display panel.

2. Description of related art

A video display apparatus such as a liquid crystal television and a plasma television tends to decrease in thickness year by year. However, if the decrease of thickness is intended, a depth space becomes small, which makes it difficult to obtain a sufficient strength of the entire apparatus. As a conventional technique for solving this problem to ensure the strength while keeping the depth of the video display apparatus thin, there is known the one described in JP-A-2006-39062, for example.

JP-A-2006-39062 discloses to arrange a main frame as a reinforced member on a back side of a panel module and fix a reinforced frame to the main frame to increase the strength of the main frame, so that the strength of the entire video display apparatus is ensured while decreasing the thickness thereof.

### BRIEF SUMMARY OF THE INVENTION

In recent years, a video display apparatus is required to be not only reduced in thickness, but also increased in size. In order to achieve the reduction in thickness and the increase in size, it becomes necessary to ensure not only the strength against a bending load in a vertical direction of the entire video display apparatus, but also the strength against a torsion load thereof.

The technique described in JP-A-2006-39062 increases the strength by fixing the reinforced frame to the two main frames arranged on the back side of the panel module as reinforcing members. While it is effective for a bending load in a vertical direction of the entire video display apparatus, the technique does not consider a torsion load at all.

The present invention is made in view of the above problem, and provides a technique for enabling the reduction in thickness and the increase in size while increasing the strength against a torsion load of the entire video display apparatus.

The present invention is characterized in that at least two frames are provided on a back surface of a base chassis on a front surface of which a display panel is arranged, and a plate-like shield cover is fixed to the two frames across those. By arranging a substrate for driving and controlling the display panel between the two frames to which the shield cover is fixed, the substrate may be covered with the shield cover.

According to the above configuration, the strength against a bending load and a torsion load of the entire video display apparatus can be increased by attaching the shield cover to at least two frames among the frames arranged on the back surface of the base chassis to three-dimensionally support the display apparatus by the base chassis, the frames and the reinforcing members, as described above.

According to the present invention, it becomes possible to decrease in thickness and increase in size while enhancing the stiffness of the video display apparatus.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWINGS

FIG. 1 is a front perspective view of a video display apparatus to which the present invention is applied;

FIG. 2 is an exploded perspective view of a liquid crystal panel module according to the present embodiment;

FIG. 3A is a view showing a base chassis and a panel frame according to the present embodiment;

FIG. 3B is a view showing a screw fixation portion of the base chassis and the panel frame according to the present embodiment;

FIG. 4 is a view showing a screw fixation portion of the panel frame and a panel supporting member according to the present embodiment;

FIG. 5 is a view showing a screw fixation portion of the panel module, a frame and a shield according to the present embodiment;

FIG. 6 is a cross sectional view taken along line B-B of FIG. 5 in a state where the panel module, the frame and the shield cover are assembled;

FIG. 7 is a cross sectional view showing one example of a heat dissipating structure utilizing a shield cover according to the present embodiment;

FIG. 8 is a view showing a state of a back surface in which frames 162 and a shield cover 163 are attached to a base chassis 122 according to the present embodiment; and

FIG. 9 is a view showing a back surface of the video display apparatus according to the present embodiment.

### DETAILED DESCRIPTION OF THE INVENTION

Hereinafter, the embodiment of the video display apparatus according to the present invention will be described with reference to the drawings taking a liquid crystal color television using a side-edge type LED backlight liquid crystal panel module for example.

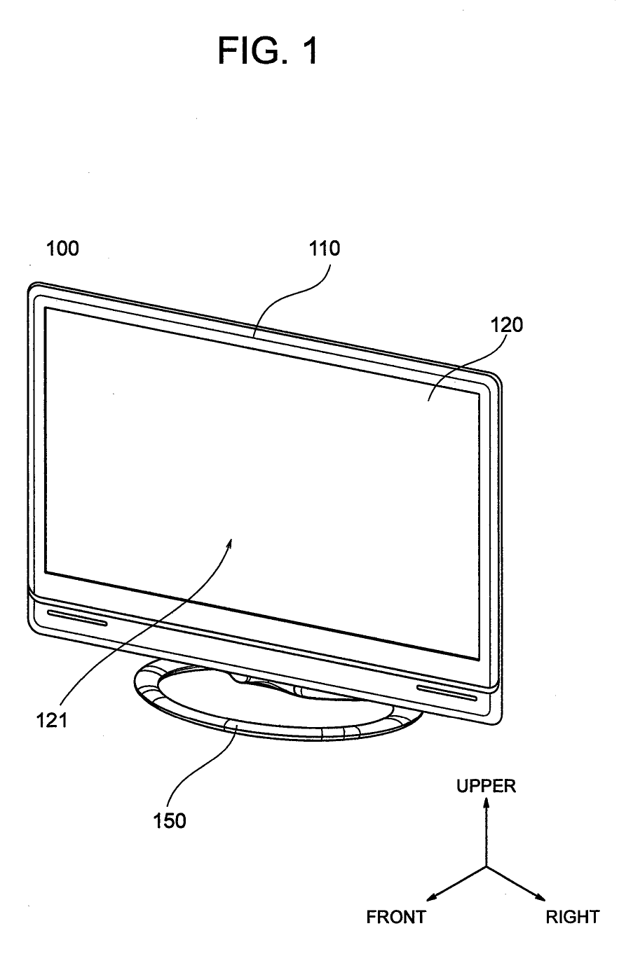

FIG. 1 is a perspective view of a video display apparatus according to the present invention. The video display apparatus 100 includes a panel module 120 and a front bezel 110 which is a housing surrounding the periphery thereof. In the video display apparatus 100, a display screen 121 provided by the panel module 120 appears from a front opening of the front bezel 110 and stands alone by means of a stand 150.

For the sake of convenience in description, upper, lower, left, right, front and back are defined with respect to the display screen 121 of the video display apparatus 100. That is, when a user viewing the video display apparatus 100 opposes the display screen 121, the side of the display screen 121 near the user is defined as “front surface”, the far side is defined as “back surface”, the horizontal right side of the video display apparatus 100 viewed from the user is defined as “right”, and the horizontal left side thereof is defined as “left”. Further, the vertical upper side of the video display apparatus 100 viewed from the user is defined as “upper”, and the vertical lower side thereof is defined as “lower”. A back cover (not shown) is arranged at the back side of the panel module 120.

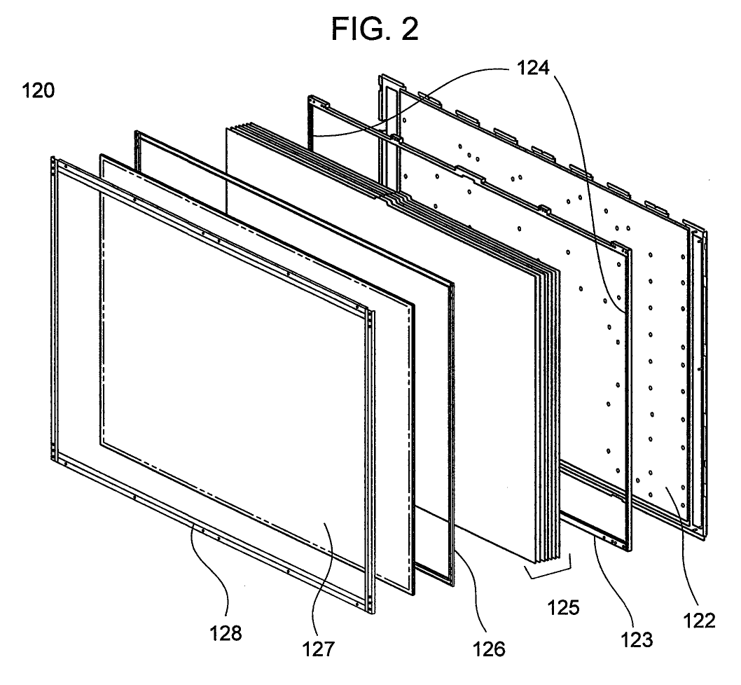

Referring to FIGS. 2 to 4, there is described one example of a configuration on the front side of a base chassis 122 of the panel module 120 according to the present embodiment, and an attachment structure of various elements on the front side.

FIG. 2 is an exploded perspective view of the panel module 120 according to the present embodiment. The panel module 120 according to the present embodiment includes the base chassis 122, a panel frame 123, an optical sheet group 125 including a plurality of optical sheets, a first panel supporting member 126, a liquid crystal panel 127 and a second panel supporting member 128. The liquid crystal panel 127 is configured such that a liquid crystal is sandwiched between two substrates, and has a function as an optical shutter which turns on and off a liquid crystal of each pixel based on an inputted video signal to control the transmission/shielding of light incident from the optical sheet group 125.

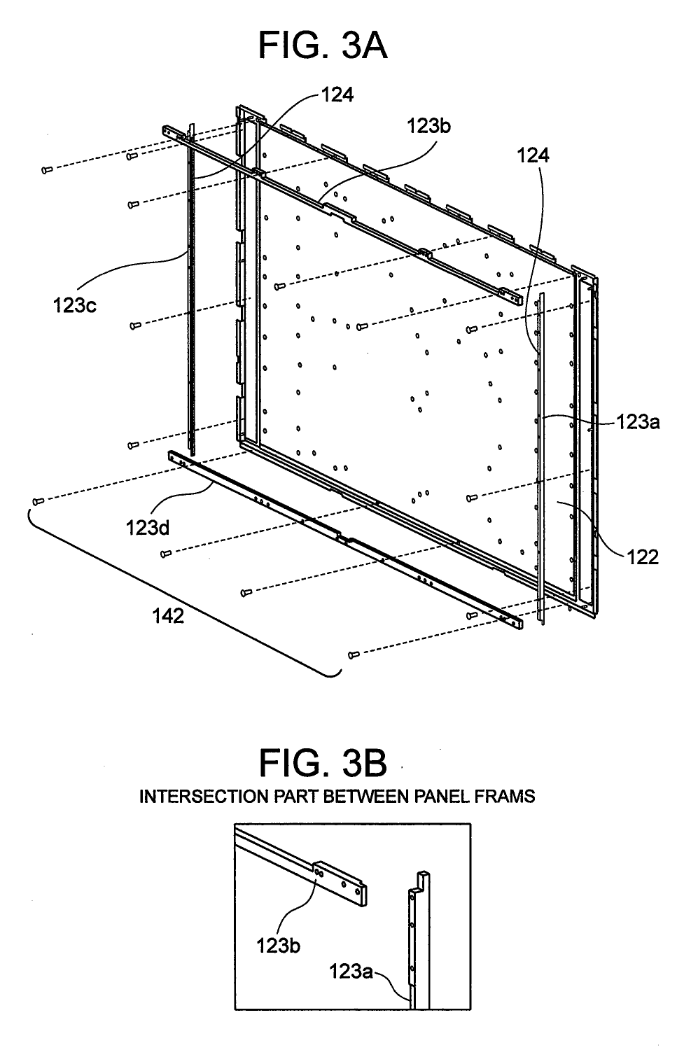

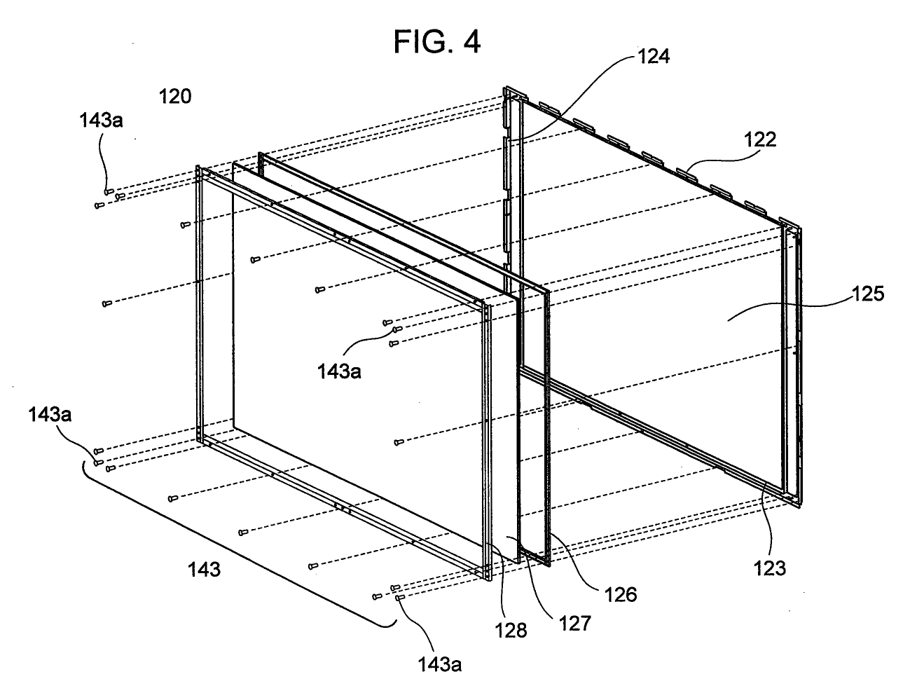

As illustrated in FIG. 2, the optical sheet group 125 and the liquid crystal panel 127 are fixed by the panel frame 123, the first panel supporting member 126 and the second panel supporting member 128 to be arranged on the front side of the base chassis 122. The fixing is described in detail below with reference to FIGS. 3 and 4.

FIG. 3 is an exploded view illustrating a configuration concerning attachment of the panel frame 123 and the base chassis 122. The base chassis 122 and the panel frame 123 are a metallic member such as stainless steel, iron and aluminum for example, and are preferably the same material, but may be different materials as long as the materials are metal.

The panel frame 123 is composed of four bar-like members 123a to 123d, made a square frame shape as illustrated in the figure, and fixed to the base chassis 122 by a plurality of first panel fixing screws 142. Light source modules 124 which are configured or arranged so that light travels inward are mounted on the right and the left panel frames 123a and 123c. The light source module 124 is composed of a plurality of light emitting diodes (LED) and is formed such that a plurality of groups of, for example, red, blue and green LEDs are arranged along the longitudinal direction of the panel frame 123. A group of LEDs is not always formed of a red, blue and green one, but a white diode which emits white light in itself may be used. Alternatively, a configuration where the white light is emitted by two diodes different in color (for example, yellow and blue) may be used.

Heat generated by the light source module 124 is thermally transferred from the panel frame 123 to the base chassis 122 and released at the base chassis 122.

FIG. 3B is an enlarged view illustrating a joint portion of the right panel frame 123a and the upper panel frame 123b. As illustrated in the figure, the right panel frame 123a and the upper panel frame 123b are provided with step portions respectively, and crossed with each other at the step portions to be fixed. The other three portions are similarly provided with step portions and crossed with each other at the step portions to be fixed.

FIG. 4 is an exploded perspective view illustrating a configuration relating to attachment of the base chassis 122, the optical sheet group 125 and the liquid crystal panel 127.

As illustrated in FIG. 4, the optical sheet group 125 including a plurality of optical sheets is arranged on the front side of the base chassis 122 to which the above described panel frame 123 is fixed. The optical sheet group 125 is held by the base chassis 122 on its back side and the first panel supporting member 126 on its front side to be sandwiched therebetween. The liquid crystal panel 127 is held and sandwiched between the first and the second panel supporting members 126 and 128. As illustrated in the figure, the first and the second panel supporting members 126 and 128 are fixed to the panel frame 123 by a plurality of second panel fixing screws 143. Among the screws, four panel fixing screws 143a located at the corner portions simultaneously fix the step portions which are joint portions of the four panel frames 123a to 123d. The optical sheet group 125 is made of a light guide plate and a diffusion sheet, and has a function to irradiate the front side with light of the light source module 124 incident from a side of the optical sheet group 125 so as to uniform its luminance in a plane (referred to as backlight).

The first panel supporting member 126 is formed of a resin (for example, polycarbonate in the present embodiment). A rubber sheet (not shown) is pasted on a contact portion between the first panel supporting member 126 and the liquid crystal panel 127. The second panel supporting member 128 is made of a metallic member such as stainless steel, iron and aluminum, for example, as described above, since it is a member receiving the panel fixing screws 143. Incidentally, as is the case with the first panel supporting member, a rubber sheet (not shown) is pasted on a contact portion of the second panel supporting member 128 and the liquid crystal panel 127. The rubber sheets prevent the liquid crystal panel 127 from being subjected to a load due to fixation of the screws, and function as a buffer member at the same time.

As described above, the panel frame 123 and the panel supporting members 126 and 128 are stacked on the four peripheral sides of the base chassis 122 in a thickness direction and rigidly fixed by the panel fixing screws 142, 143, so that the stiffness of the panel module 120 itself is ensured.

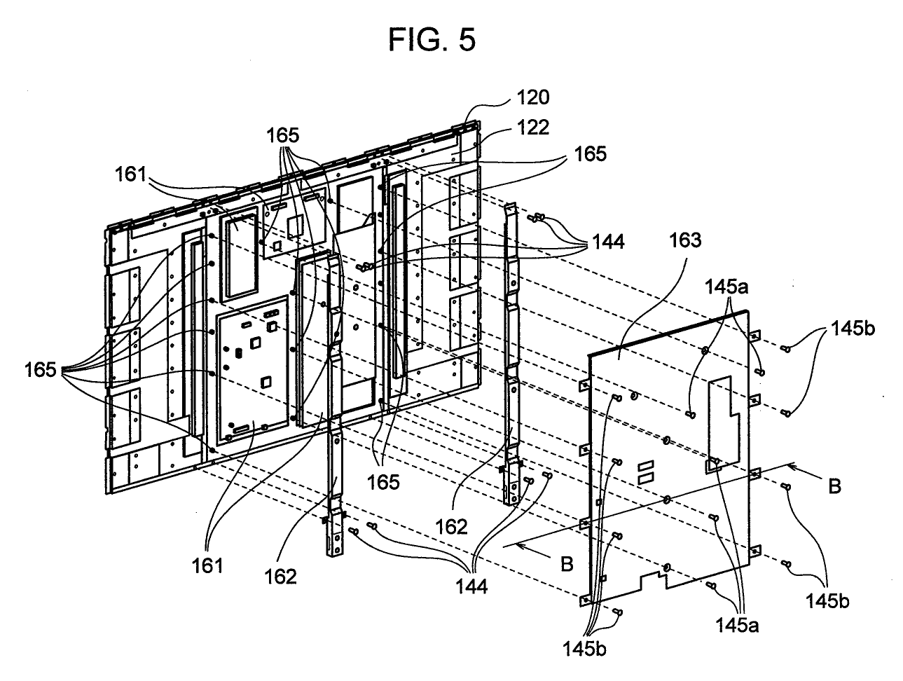

Next, referring to FIGS. 5 to 8, there is described one example of a configuration on the back side of the base chassis 122 of the panel module 120 according to the present embodiment, and an attachment structure of various elements on the front side.

FIG. 5 is an exploded perspective view illustrating an attachment structure of a substrate and a reinforced structure on the back side of the panel module 120.

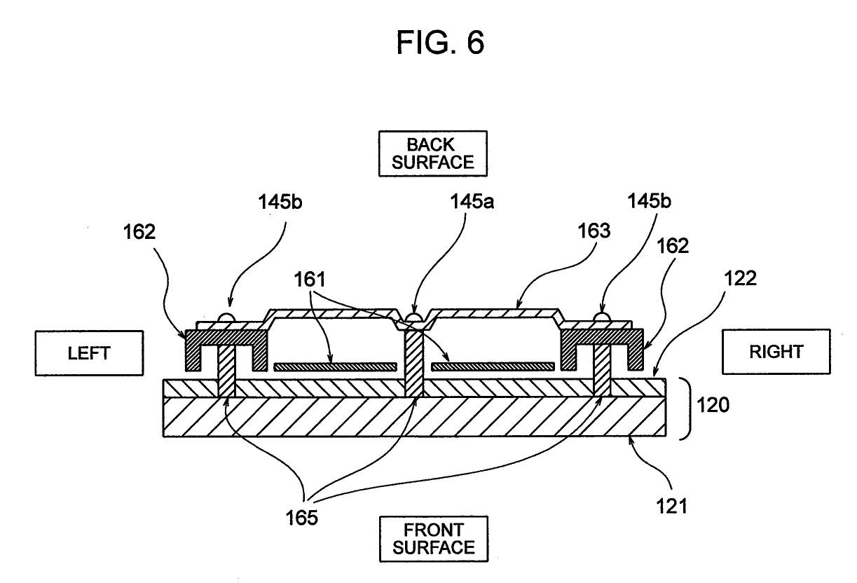

On the back side of the panel module 120, there are arranged a substrate group 161 such as a power supply substrate and a control substrate adapted to drive and/or control the liquid crystal panel 127 and the light source module 124 and a signal processing substrate. The substrate group 161 is fixed to the base chassis 122 constituting the back surface of the panel module 120, for example, by a screw (not shown). FIG. 6 is a cross sectional view taken along line B-B of FIG. 5 showing a state where the panel module 120, the frame 162 and a shield cover 163 are assembled.

The two frames 162 are a bar-like reinforcing member in which a metallic plate, for example, made of stainless steel, iron and aluminum is bent in a longitudinal direction into a U-shape and extends in a vertical direction (or in the upper and the lower direction) of the video display apparatus 100. The two frames 162 are assembled in parallel to each other by frame fixing screws 144 on the back surface of the base chassis 122. The frame fixing screws 144 reach the upper panel frame 123b and the lower panel frame 123d which are a reinforcing member of the panel module 120 and form a rigid body together with the panel module 120. Between the two frames 162, there are arranged the substrate group 161 such as a power supply circuit substrate, a control circuit substrate and a signal processing circuit substrate. In the present embodiment, all the substrate group 161 is disposed between the two frames 162, but it is not limited thereto, while at least one of the substrates may be arranged between the two frames 162. For example, the power supply circuit with a high heating value and/or the signal processing circuit radiating an electromagnetic wave may be arranged between the two frames 162 and an LED driver (not shown) for driving an LED as a light source may be arranged outside the frames 162 (on the left and right end sides of the of the video display apparatus 100). In the present embodiment, although two frames 162 are used, three or four frames may be used. The number of the frames 162 may be properly selected according to the size (the number of inches) of the liquid crystal panel 127 or the required strength.

The shield cover 163 is attached from the back side so as to cover the substrate group 161 arranged between the two frames 162 and to extend between the two frames 162. Such an attachment is performed, for example, by fixing shield fixing screws 145 to a metallic stud boss 165 fixed to the base chassis 122 by press fit or caulking as illustrated in FIG. 6. A shield fixing screw 145a at the center of the shield cover 163 fixes the shield cover 163 to the stud boss 165. Shield fixing screws 145b at the left and right sides of the shield cover 163 fix the shield cover 163 and the frames 162 to the stud bosses 165. Thus, the shield cover 163 becomes a bridge structure of the two frames 162. That is, the two frames 162 are fixed to the upper and lower panel frames 123b and 123d by the frame fixing screws 144 and to the stud boss 165 provided on the base chassis 122 by a shield fixing screw 145d, thereby securing the strength against a bending load.

Further, the shield cover 163 is two-dimensionally fixed by the shield fixing screws 145 to the base chassis 122 to ensure the strength of the shield cover 163 and the panel frame 123 against a torsion load. At the same time, by fixing the shield cover 163 to the two frames 162 so as to become the crosslink structure, the strength against a torsion load is further improved.

As described above, the one shield cover 163 is fixed to cover at least one substrate 161 and electrically grounded by the shield fixing screws 145. Thus, according to this configuration, since it is possible to completely cover an electronic component which is mounted on the substrate group 161 and may cause undesired radiation and a leakage path (such as a cable and a connector terminal connected between substrates), it is possible to effectively prevent electromagnetic jamming from leaking outside and decrease the EMI to another device.

That is to say, the shield cover 163 according to the present embodiment improves the strength against a torsion load of the video display apparatus 100 and prevents the undesired radiation from leaking outside.

Incidentally, insulating sheets (not shown) are attached between the base chassis 122 and the substrate group 161 mounted thereon, and between the substrate group 161 and the shield cover 163 to avoid an electrical contact.

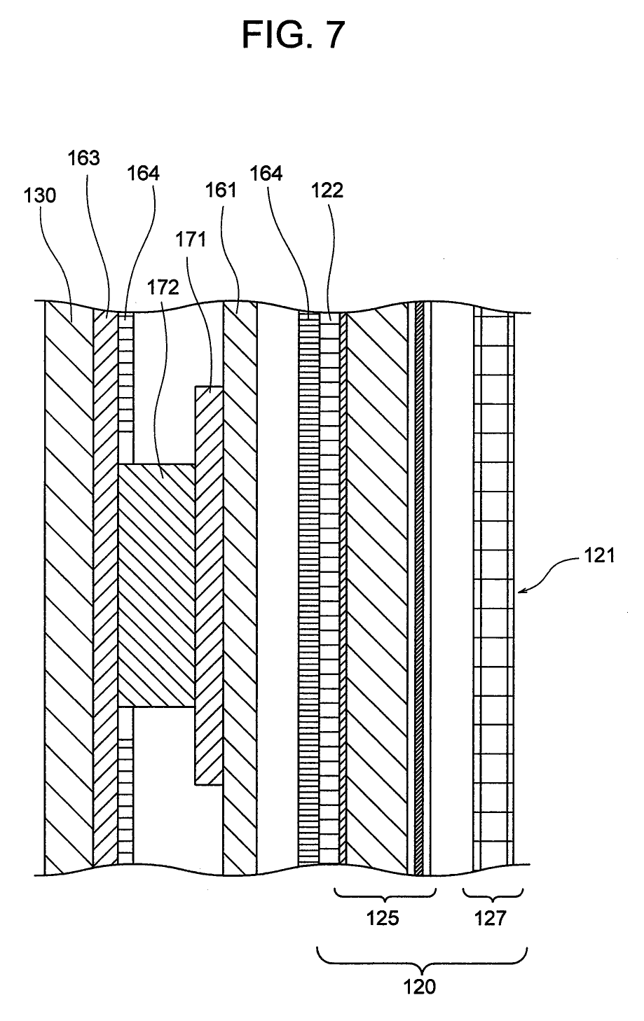

Further, it is possible to effectively cool the substrate group 161 using the shield cover 163. Hereinafter, the shield cover 163 will be described with reference to FIG. 7 in connection with a configuration relating to heat dissipation of the substrate group 161.

FIG. 7 is a cross sectional view illustrating one example of a heat dissipation configuration of a heating part 171 mounted on the substrate group 161 by means of the shield cover 163. In FIG. 7, the components given the same reference numeral as the already described components have the same configuration and function as those, and thus a duplicated description thereof is omitted.

The substrate group 161 is fixed to the back surface of the panel module 120 through an insulating sheet 164. An appropriate space is formed between the panel module 120 and the insulating sheet 164, and the substrate group 161 to provide air insulation so that heat of the substrate group 161 is not transferred to the panel module 120 or heat of the panel module 120 is not transferred to the substrate group 161. The heating part 171 (for example, a transformer of the power supply circuit, a main microcomputer (CPU) of the signal processing substrate, a decoder circuit or the like) mounted on the substrate group 161 is brought into contact with the shield cover 163 through a thermal conductive member 172 made of a thermal conductive raw material, for example, silicon rubber. For this reason, the heat generated from the heating part 171 is transferred by the thermal conductive member 172 to the shield cover 163 and released from the shield cover 163. A back cover 130 as a housing for the video display apparatus 100 is arranged on the back side of the shield cover 163. The back cover 130 may be brought into contact with the shield cover 163 through, for example, a thermal conductive member, or may not be brought into contact therewith by providing a gap therebetween.

When using the shield cover 163 having the structure of widely covering a plurality of the substrate groups 161 like the present embodiment, the area of the shield cover 163 becomes greater than the case where the shield cover 163 is used for each, single substrate, so that expansion of the cooling area is anticipated. Consequently, the cooling effect and the thermal diffusion effect are increased so that cooling of the heating part 171, and prevention of local raise in temperature of the substrate group 161 become possible.

That is, the shield cover 163 according to the present embodiment can have a function of ensuring the strength, a function of decreasing the leakage of electromagnetic jamming to the outside and a function of cooling the heating part 171.

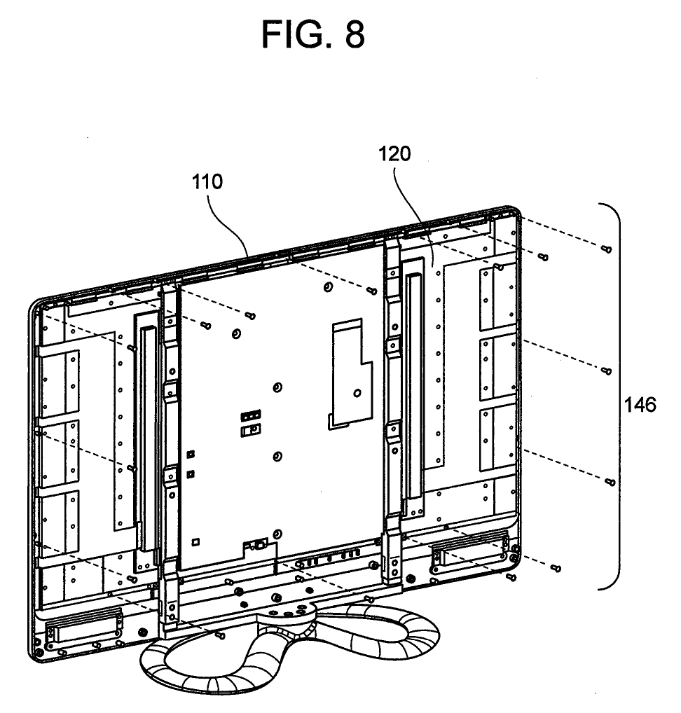

FIG. 8 is a perspective view illustrating the back surface in which the bar-like frames 162 and the shield cover 163 are fixed to the base chassis 122 and, a configuration relating to attachment of the front bezel 110 and the stand 150. In the figure, the back cover 130 is removed.

As illustrated in FIG. 8, the front bezel 110 is fixed to the panel module 120 along the outer peripheral thereof by bezel fixing screws 146. The stand 150 is fixed to the two frames 162 by screws (not shown). By this configuration, a load applied to the stand 150 based on the deadweight of the video display apparatus 100 is distributed to the two bar-like frames 162 as reinforcing members and the shield cover 163 fixed to the frame 162 as a reinforced member, and therefore such a load is prevented from being applied directly to the liquid crystal panel 127. Thus, according to the present embodiment, it is possible to further increase the strength against a load applied to the video display apparatus when the video display apparatus 100 is placed stationary by using the stand 150. Such an effect can be similarly provided in the case where the video display apparatus 100 is placed and hung on a wall.

When the video display apparatus is placed and hung on a wall, the video display apparatus 100 is hung on the wall by, for example, removing the stand 150 from the two frames 162, attaching a wall-hang metal fitting (not shown) to the two frames 162 instead of the stand, and hanging the wall-hang metal fitting on the wall. Also in this case, although a load based on the deadweight of the video display apparatus 100 is applied to the video display apparatus 100 through the wall-hang metal fitting, such a load is distributed to the two frames 162 and the shield cover 163, and therefore such a load is prevented from being applied directly to the liquid crystal panel 127. Thus, according to the present embodiment, it is possible to further increase the strength against a load applied to the video display apparatus 100 when the video display apparatus 100 is placed and hung on a wall.

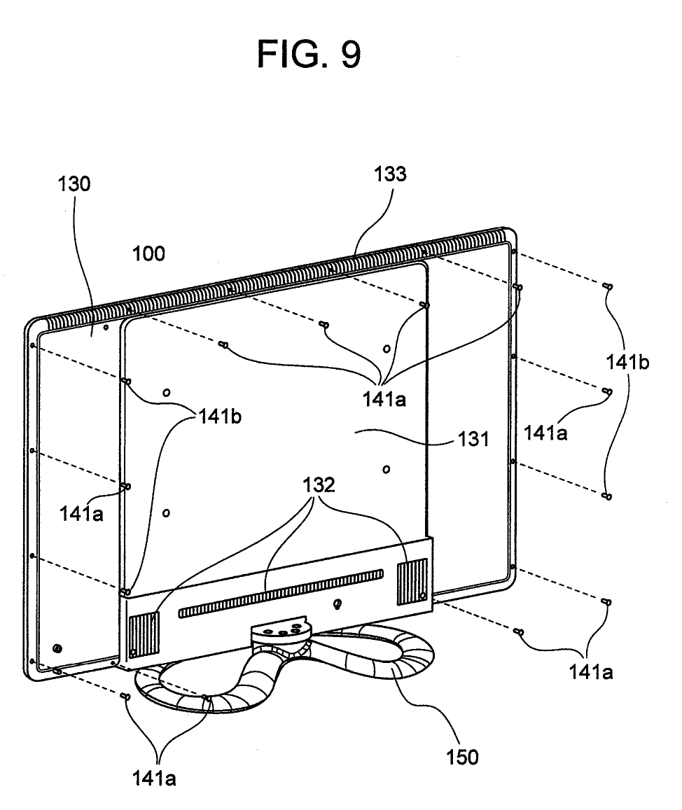

Next, the appearance of the video display apparatus 100 viewed from the back side thereof and the fixing structure of the back cover 130 will be described with reference to FIG. 9.

As illustrated in FIG. 9, the back cover 130 is similarly fixed to the front bezel 110 along the outer peripheral thereof by cover fixing screws 141. In this configuration, cover fixing screws 141b of the back cover 130 other than cover fixing screws 141a are fixed also to the panel frame 123 through the base chassis 122. This makes appearance parts to form a box shape, which has a function of reinforcing the panel module 120.

In this embodiment, a protruding portion 131 which protrudes toward the back side of the video display apparatus 100 with respect to another portion is provided on a portion of the back cover 130 which corresponds to the two frames 162 and the shield cover 163 in position. An air inlet 132 for letting air flow into a space inside the protruding portion 131 is provided below the protruding portion 131. An air outlet 133 which discharges air inside the protruding portion 131 is provided on a portion above the protruding portion 131.

By forming the portion of the back cover 130 corresponding to the two frames 162 and the shield cover 163 in position as the protruding portion 131 which protrudes toward the back side of the video display apparatus 100, the cooling area including the substrate group 161 having the heating part 171 (that is, the area where the space is in contact with the air outside the video display apparatus 100) becomes increased, so that cooling of the substrate group 161 is performed more preferably. Further, if the air inlet 132 and the air outlet 133 are provided below and above the protruding portion 131, respectively, it is possible to make air flow into the space in the protruding portion 131 (see FIG. 7) so as to flow the air through the space between the base chassis 122 and the substrate group 161 and the space between the substrate group 161 and the shield cover 163. According to such a configuration, therefore, the substrate group 161 lying in the protruding portion 131 can be more preferably cooled.

According to the present embodiment, each element of a panel module portion, an internal mechanism portion and an appearance portion has a structure for increasing stiffness. Further, the frame fixing screws 144 and shield fixing screws 145 firmly fix between “the panel module portion and the internal mechanism portion”, and the cover fixing screws 141 firmly fix between “the internal mechanism portion and the appearance portion”, and between “the panel module portion and the appearance portion”. In other words, since the reinforced structures of respective elements are rigidly fixed together by screws, respective structures act on each other synergistically, so that the flexural rigidity and the stiffness in torsion of the entire video display apparatus 100 are reinforced, and the video display apparatus can be decreased in thickness.

Although the present embodiment has described above with respect to the side-edge type LED backlight liquid crystal display, the present embodiment is applicable to various panel modules irrespective of a backlight type. In addition, the present embodiment is similarly applicable not only to a liquid crystal panel, but also to a plasma display panel (PDP).

The present invention is not limited to the embodiments described above and illustrated in the figures, but various modifications may be made without departing from the spirit thereof.

1. A video display apparatus comprising:
a base chassis on a front surface of which a display panel is arranged and on a back surface of which at least one substrate for driving and/or controlling the display panel is arranged;
at least two frames attached to the back surface of the base chassis in parallel with each other; and
a plate-like shield cover attached to the at least two frames to extend therebetween.

2. The video display apparatus according to claim 1, wherein the at least one substrate is disposed between the at least two frames to which the shield cover is attached, and the substrate is covered with the shield cover.

3. The video display apparatus according to claim 2, wherein the shield cover covers a part of the substrate.

4. The video display apparatus according to claim 1, wherein the shield cover is fixed further to the base chassis, or to a fixation part provided on the base chassis.

5. The video display apparatus according to claim 1, wherein the shield cover is thermally connected to a thermal conductive member attached to a heating part on the substrate.

6. A video display apparatus comprising:
a display panel for displaying a screen image;
a base chassis on a front surface of which the display panel is arranged;
at least two frames attached to a back surface of the base chassis in parallel with each other;
a substrate arranged between the at least two frames for driving and/or controlling the display panel;
a plate-like shield cover attached to the at least two frames holding the substrate therebetween, the plate-like shield cover extending between the least two frames; and
a back cover arranged on a back surface of the shield cover, the back cover acting as a housing for covering a back surface of the video display apparatus.

7. The video display apparatus according to claim 6, wherein a portion of the back cover corresponding to the at least two frames and the shield cover is made a protruding portion which protrudes toward the back surface side of the video display apparatus than another portion.

8. The video display apparatus according to claim 7, wherein an air inlet for allowing air to flow into the inside of the video display apparatus is provided below the protruding portion of the back cover.

9. The video display apparatus according to claim 6, wherein the substrate is a power supply circuit.
